(19) United States
(12) Patent Application Publication
(10) Pub. No.: US 2013/0081868 A1
(43) Pub. Date: Apr. 4, 2013

(54) PRINTED CIRCUIT BOARD

(71) Applicants: Dong Hwan LEE, Gyeonggi-do (KR); Seung Wook Park, Seoul (KR); Kyung Sang Lim, Gyeonggi-do (KR); Young Do Kweon, Seoul (KR)

(72) Inventors: Dong Hwan LEE, Gyeonggi-do (KR); Seung Wook Park, Seoul (KR); Kyung Sang Lim, Gyeonggi-do (KR); Young Do Kweon, Seoul (KR)

(73) Assignee: SAMSUNG ELECTRO-MECHANICS CO., LTD., Suwon (KR)

(21) Appl. No.: 13/355,797

(22) Filed: Jan. 23, 2012

(30) Foreign Application Priority Data
Sep. 30, 2011 (KR) 10-2011-0099537

(51) Int. Cl. H05K 1/11

(52) U.S. Cl. 174/261

(57) ABSTRACT

Disclosed herein is a printed circuit board, including: a dielectric substrate having a ground surface; a plurality of pads formed on the dielectric substrate; a transmission line transmitting a signal between the plurality of pads; and slots formed in partial regions of the ground surface correspondingly to the pads, thereby to improve signal transmitting characteristics and allow high-density wiring and thin thickness.

### CROSS REFERENCE(S) TO RELATED APPLICATIONS

This application claims the benefit under 35 U.S.C. Section 119 of Korean Patent Application Serial No. 10-2011-0099537, entitled “Printed Circuit Board” filed on Sep. 30, 2011, which is hereby incorporated by reference in its entirety into this application.

### BACKGROUND OF THE INVENTION

1. Technical Field

The present invention relates to a printed circuit board including transmission lines transmitting signals between a plurality of pads and a plurality of pads, and more particularly to a printed circuit board capable of improving signal transmitting characteristics by removing parasitic components generated between the pads and the transmission lines.

2. Description of the Related Art

In accordance with the recent development of the electronic industry, the demand for multi-functional and slim and light electronic components has rapidly increased. Therefore, a printed circuit board having the electronic components mounted thereon has also been demanded to have high density wiring and a thin thickness. In order to reflect these demands, developments have progressed so as to lower the thickness of a core material in a substrate manufacturing process. However, there is a limitation in driving using mass-production equipment in order to lower the thickness of the core material.

For this reason, in the related art, a printed circuit board was manufactured by forming a thin dielectric on a surface of the core material and plating an electrode pattern on the dielectric.

FIG. 1 is a cross sectional view of a printed circuit board according to the related art, and FIG. 2 is a plan view of the printed circuit board according to the related art.

FIGS. 1 and 2 show a printed circuit board having high-density wirings and thin thickness according to the related art. In the printed circuit board, a dielectric 2 having a thin thickness is formed on a surface of a core material 1. An electrode pattern 3 including plural pads 3a and 3b and a transmission line 3c is formed above the dielectric 2 and a ground surface 4 is formed below the dielectric 2.

According to the printed circuit board having the structure as above, high-density wiring is achieved because the dielectric 2 is very thin and the transmission line 3c has a very narrow line width. However, line widths of the pads 3a and 3b become very increased as compared with the line width of the transmission line 3c, with the result that a parasitic component generated at impedance discontinuous points between the pads 3a and 3b and the transmission line 3c may become very increased.

Further, a parasitic capacitance generated between the pads 3a and 3b and the ground surface 4 may cause to deteriorate signal transmitting characteristics.

FIG. 3 is a graph showing signal transmitting characteristics of the printed circuit board according to the related art, which shows signal transmitting characteristics in a case where a thickness of a dielectric is set to 10 μm. It can be seen that signal transmission loss (−1.93 dB at 2.45 GHz, a first curve \textcircled{1}) and signal reflection loss (−6 dB at 2.45 GHz, a second curve \textcircled{2}) are very large in the printed circuit board according to the related art.

Therefore, when the printed circuit board of the related art is used to embody a module or a system, transmission power is reduced in a signal transmitter and a signal receiving sensitivity is deteriorated in a signal receive, which is caused by an increase in signal loss, resulting in deterioration in performance of the entire system.

Therefore, a printed circuit board, which has high-density wiring and thin thickness without deteriorating signal transmitting characteristics, has been needed in those skilled in the art.

### SUMMARY OF THE INVENTION

An object of the present invention is to provide a printed circuit board capable of allowing high-density wiring and slim thickness and improving signal transmitting characteristics by forming slots in partial regions of a ground surface facing pads.

According to an exemplary embodiment of the present invention, there is provided a printed circuit board, including: a dielectric substrate having a ground surface; a plurality of pads formed on the dielectric substrate; a transmission line transmitting a signal between the plurality of pads; and slots formed in partial regions of the ground surface correspondingly to the pads.

The slots may be formed by partially removing the ground surface at positions facing the pads.

The slots may be formed by partially removing the ground surface at a position facing the transmission line.

The dielectric substrate may be made of a dielectric material.

The number of slots may be the same as the number of pads.

The slot may have a larger area than the pad.

The ground surface may be a conductive film coated on one surface of the dielectric substrate.

The printed circuit board may further include a core substrate having the dielectric substrate formed on one surface thereof.

The dielectric substrate may be constituted of first and second dielectric substrates formed on upper and lower surfaces of the core substrate.

The first dielectric substrate may have pads and a transmission line formed on an upper surface thereof and the second dielectric substrate may have pads and a transmission line formed on a lower surface thereof.

The first dielectric substrate may have a ground surface formed on the lower surface thereof and the second dielectric substrate may have a ground surface formed on the upper surface thereof.

The dielectric substrate may have a thickness of ⅕ times or less of that of the core substrate.

The transmission line may have a line width of ⅕ times or less of that of the pad.

### BRIEF DESCRIPTION OF THE DRAWINGS

FIG. 1 is a cross sectional view of a printed circuit board according to the related art;

FIG. 2 is a plan view of the printed circuit board according to the related art;

FIG. 3 is a graph showing signal transmitting characteristics of the printed circuit board according to the related art;

FIG. 4 is a cross-sectional view of a printed circuit board according to one exemplary embodiment of the present invention;

FIG. 5 is a plan view of the printed circuit board shown in FIG. 4;

FIG. 6 is a graph showing signal transmitting characteristics when a dielectric substrate has a thickness of 10 μm in the printed circuit board shown in FIG. 4;

FIG. 7 is a graph showing signal transmitting characteristics when a dielectric substrate has a thickness of 30 μm on the printed circuit board shown in FIG. 4;

FIG. 8 is a plan view of a printed circuit board according to another exemplary embodiment of the present invention;

FIG. 9 is a graph showing signal transmitting characteristics when a dielectric substrate has a thickness of 10 μm on the printed circuit board shown in FIG. 8;

FIG. 10 is a plan view of a printed circuit board according to still another exemplary embodiment of the present invention;

FIG. 11 is a graph showing signal transmitting characteristics of the printed circuit board shown in FIG. 10;

FIG. 12 is a plan view of the printed circuit board as shown in FIG. 10, of which a transmission line has a changed line width; and

FIG. 13 is a graph showing signal transmitting characteristics of the printed circuit board shown in FIG. 12.

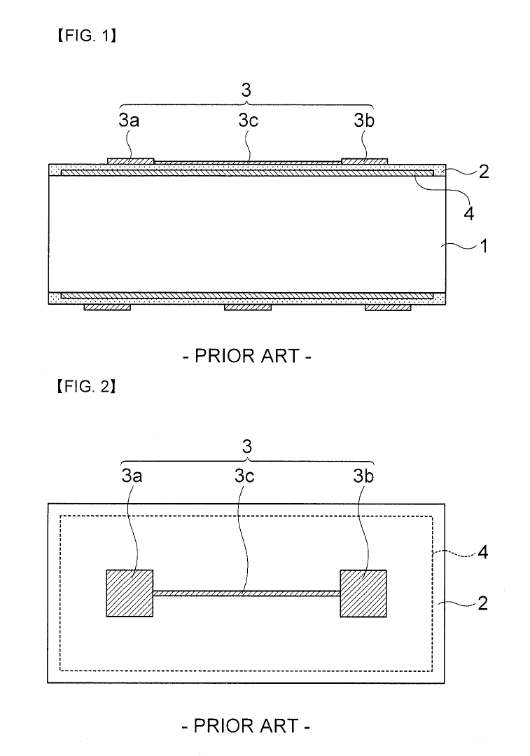

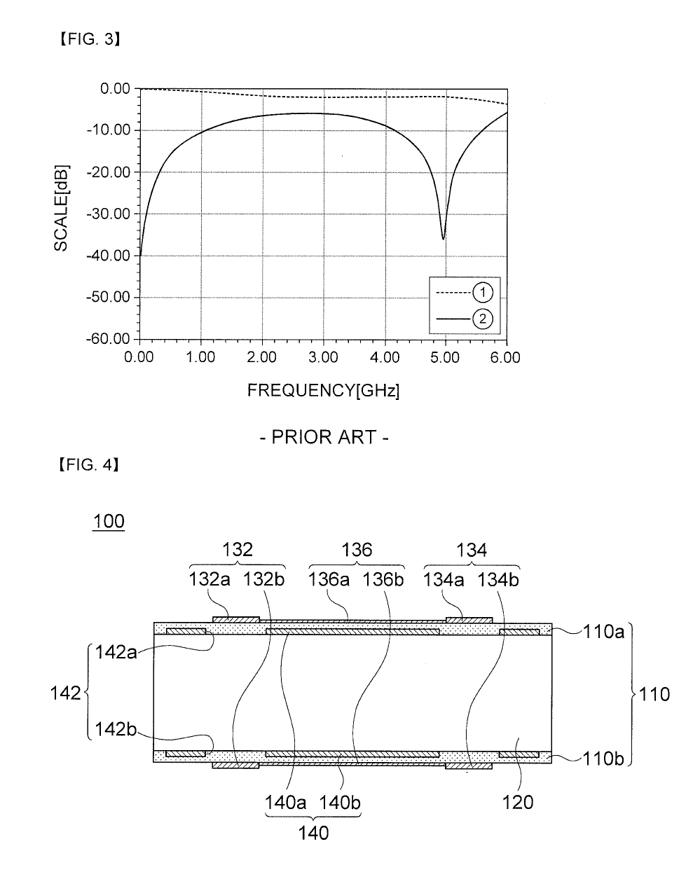

### DESCRIPTION OF THE PREFERRED EMBODIMENTS

Terms and words used in the present specification and claims are not to be construed as a general or dictionary meaning but are to be construed meaning and concepts meeting the technical ideas of the present invention based on a principle that the inventors can appropriately define the concepts of terms in order to describe their own inventions in the best mode.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, embodiments of the present invention will be described with reference to the accompanying drawings.

FIG. 4 is a cross-sectional view of a printed circuit board according to one exemplary embodiment of the present invention; and FIG. 5 is a plan view of the printed circuit board shown in FIG. 4.

As shown in FIGS. 4 and 5, a printed circuit board 100 includes a dielectric substrate 110, a core substrate 120, a plurality of pads 132 and 134, a transmission line 136, and slots 142.

The dielectric substrate 110 may be made of a dielectric material. Here, as a material for the dielectric substrate 110, relatively cheap glass epoxy (FR4) may be used. However, without being limited to, any one of epoxy, duroid, Teflon, Bakelite, high-resistance silicon, glass, alumina, LTCC, and air form may be also used.

In addition, the dielectric substrate 110 may have a ground surface 140, and this ground surface 140 maybe constituted of a conductive film coated on one surface of the dielectric substrate 110.

The dielectric substrate 110 may have a thickness of ⅕ or less of that of the core substrate 120. As such, the dielectric substrate 110 is embodied to have a very thin thickness as compared with the core substrate 120, and thus, the entire printed circuit board 100 can be slimmed and allow high-density wiring.

The core substrate 120 serves to support the printed circuit board 100 in the center, and the dielectric substrate 110 may be formed on one surface or both surfaces of the dielectric substrate 110. If the dielectric substrate 110 is formed on both surfaces of the core substrate 120, the dielectric substrate 110 maybe constituted of first and second dielectric substrates 110a and 110b, which are formed on an upper surface and a lower surface of the core substrate 120.

The pads 132 and 134 are members mounting devices or parts thereon, and the number of pads is plural in number. In addition, the pads 132 and 134 maybe formed on the dielectric substrate 110. If the dielectric substrate 110 is constituted of the first and second dielectric substrates 110a and 110b formed on both surfaces of the core substrate 120, the pads 132 and 134 may constituted of first pads 132a and 132b formed on the upper surface of the first dielectric substrate 110a and the second pads 132b and 134b formed the lower surface of the second dielectric substrate 110b.

Meanwhile, two pads are shown in the drawings, for convenience of description. However, the number of pads is not limited, and for example, three or more pads may be used.

The transmission line 136 serves to transmit a signal between the plurality of pads 132 and 134. If the dielectric substrate 110 is constituted of the first and second dielectric substrates 110a and 110b formed on both surfaces of the core substrate 120, the transmission line 136 may be constituted of a first transmission line 136a formed on an upper surface of the first dielectric substrate 110a and a second transmission line 136b formed on a lower surface of the second dielectric substrate 110b.

Here, the transmission line 136 may have a line width of ⅕ or less of that of the pads 132 or 134. In other words, a line width ratio of the transmission line 136 to the pad 132 or 134, for signal transmission, is embodied to 1:5 or more, and thus density of wiring can be increased correspondingly to the dielectric substrate 110 having a thin thickness.

The slots 142 are members that are formed by removing partial regions of the ground surface 140, corresponding to the pads 132 and 134, and may have a defected ground structure (DGS) in order to improve signal transmitting characteristics.

Here, the slots 142 maybe formed in the ground surface 140 at positions facing the pads 132 and 134, and if the number of pads 132 and 134 is plural in number, the slot 142 also may be embodied in plural in number. As such, if the slots 142 are formed in the ground surface 140 at positions facing the pads 132 and 134, an impedance component across the pads 132 and 134 becomes increased, with the result that an impedance difference between the transmission line 136 and the pads 132 and 134 becomes reduced and the number of discontinuous points is decreased, and thus, a parasitic capacitance generated at the pads 132 and 134 can be reduced.

In addition, the slot 142 is constituted to have an area larger than that of the pad 132 or 134. Here, the parasitic capacitance generated at an impedance discontinuity point between the pads 132 and 134 and the transmission line 136 and the parasitic capacitance generated between the pads 132 and 134 and the ground surface 140 can be effectively removed only when the slots 142 are formed at the positions facing the pads 132 and 134 and the slots 142 have an area larger than the pads 132 or 134, as described above, and as the result, signal transmitting characteristics can be significantly improved.

If the dielectric substrate 110 is constituted of the first and second dielectric substrates 110a and 110b formed on both surfaces of the core substrate 120, the slot 142 may be constituted of a first slot 142a formed in the first ground surface 140a disposed on the lower surface of the first dielectric substrate 110a and a second slot 142b formed in the second ground surface 140b disposed on the upper surface of the second dielectric substrate 110b.

Meanwhile, if the printed circuit board 100 is a multilayered printed circuit board having four layers or more based on the core substrate 120, the slots 142 may be embodied up-and-down symmetrically. For example, in a case where the dielectric substrates positioned from the top to the bottom are sequentially referred to as first to fourth dielectric substrates, slots maybe formed in a ground surface of the second dielectric substrate when the pads and the transmission line are formed on the first dielectric substrate, and slots may be formed in a ground surface of the third dielectric substrate when the pads and the transmission line are formed on the fourth dielectric substrate.

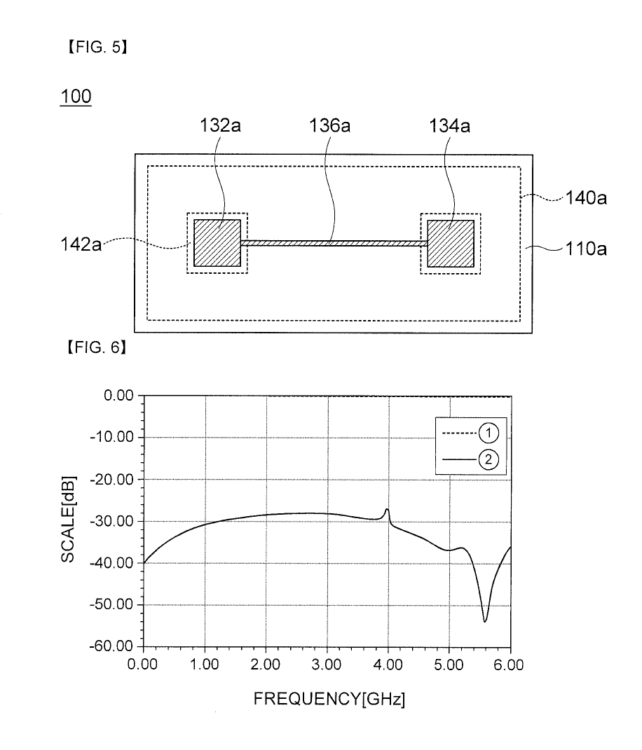

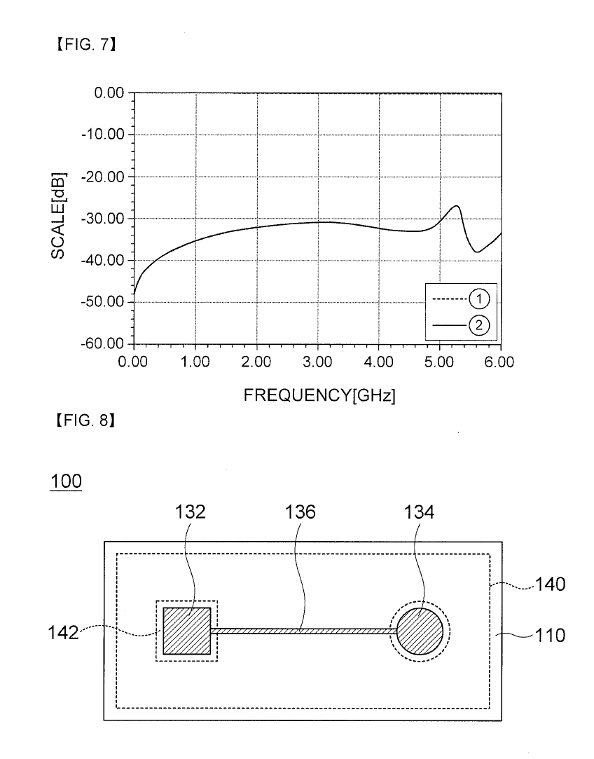

FIG. 6 is a graph showing signal transmitting characteristics when a dielectric substrate has a thickness of 10 μm in the printed circuit board shown in FIG. 4; and FIG. 7 is a graph showing signal transmitting characteristics when a dielectric substrate has a thickness of 30 μm in the printed circuit board shown in FIG. 4.

Referring to FIG. 6, a first curve \textcircled{1} shows a signal transmission loss and a second curve \textcircled{2} shows a signal reflection loss. As the first curve \textcircled{1} rises up and the second curve \textcircled{2} falls down, the signal transmitting characteristics are better.

It can be seen from FIG. 6 that signal transmitting characteristics of the printed circuit board 100 having the dielectric substrate 110 with a thickness of 10 μm are significantly improved as compared with those of the printed circuit board of the related art as shown in FIG. 3, because it has a signal transmitting loss of −0.30 dB at 2.45 GHz on the first curve \textcircled{1} and a signal reflection loss of −28 dB at 2.45 GHz on the second curve \textcircled{2}.

Also, it can be seen from FIG. 7 that signal transmitting characteristics of the printed circuit board 100 having the dielectric substrate 110 with a thickness of 30 μm are significantly improved as compared with those of the printed circuit board of the related art as shown in FIG. 3, because it has a signal transmitting loss of −0.15 dB at 2.45 GHz on the first curve \textcircled{1} and a signal reflection loss of −20 dB at 2.45 GHz on the second curve \textcircled{2}.

As shown in FIGS. 6 and 7, the reason why the signal transmitting characteristics are significantly improved is that the parasitic component generated at an impedance discontinuity point between the pads 132 and 134 and the transmission line 136 and the parasitic capacitance generated between the pads 132 and 134 and the ground surface 140 are significantly decreased to improve transfer characteristics of the transmission line 136, and it can be seen that the thinner the dielectric substrate 110, the larger this improvement in transfer characteristics of the transmission line 136.

That is to say, as shown in FIG. 7, transfer characteristics of the transmission line 136 in the printed circuit board having the dielectric substrate 110 with a thickness of 30 μm can be significantly improved as compared with those in the printed circuit board having the dielectric substrate 110 with a thickness of 10 μm, as shown in FIG. 6.

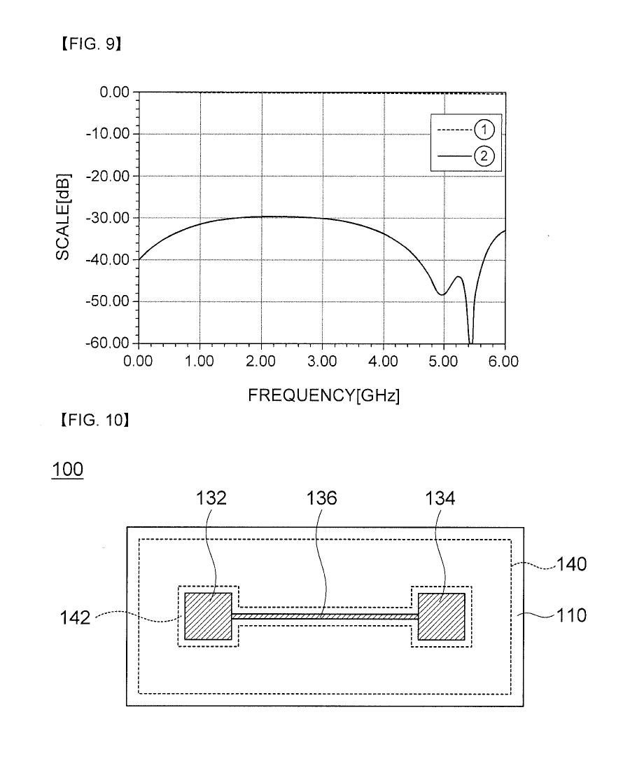

FIG. 8 is a plan view of a printed circuit board according to another exemplary embodiment of the present invention and FIG. 9 is a graph showing signal transmitting characteristics when a dielectric substrate has a thickness of 10 μm in the printed circuit board shown in FIG. 8.

As shown in FIG. 8, a printed circuit board 100 includes a dielectric substrate 110, a core substrate 120, a plurality of pads 132 and 134, a transmission line 136, and slots 142. Here, detailed descriptions of the same technical components as the printed circuit board according to the exemplary embodiment of the present invention described as above will be omitted, and the same reference numerals will be used for the same technical components.

The pads 132 and 134 may be in a circular shape. If the pads 132 and 134 are in a circular shape as such, the pads 132 and 134 may be constituted as a ball pad of an integrated circuit (IC) having a ball grid array (BGA) type or a chip scale package (CSP) type.

Also, if the pads 132 and 134 are in a circular shape, the slots 142 may be in a circular shape.

FIG. 9 is a graph showing signal transmitting characteristics when a dielectric substrate has a thickness of 10 μm in the printed circuit board. It can be seen from FIG. 9 that signal transmitting characteristics of this printed circuit board are significantly improved as compared with those of the printed circuit board of the related art as shown in FIG. 3, because it has a signal transmitting loss of −0.15 dB at 2.45 GHz on the first curve \textcircled{1} and a signal reflection loss of −30 dB at 2.45 GHz on the second curve \textcircled{2}.

In addition, since the same effect is generated regardless of the shape of the pad 132 or 134 or the slot 142, various shapes of the pads 132 and 134 or slot 142 can be embodied according to the structure and characteristics of the printed circuit board 100.

FIG. 10 is a plan view of a printed circuit board according to still another exemplary embodiment of the present invention; and FIG. 11 is a graph showing signal transmitting characteristics of the printed circuit board shown in FIG. 10.

As shown in FIG. 10, a printed circuit board 100 includes a dielectric substrate 110, a core substrate 120, a plurality of pads 132 and 134, a transmission line 136, and slots 142. Here, detailed descriptions of the same technical components as the printed circuit board according to the exemplary embodiment of the present invention described as above will be omitted, and the same reference numerals will be used for the same technical components.

Also, the slot 142 may be formed in the ground surface 140 at the position facing the transmission line 136 in addition to the pads 132 and 134. That is to say, in the printed circuit board according to another exemplary embodiment of the present invention, the slots 142 maybe formed by removing partial regions of the ground surface 140, which face the pads 132 and 134 and the transmission line 136.

As such, when the slot 142 is formed in the partial region of the ground surface 140 facing the transmission line 136, signal transmitting characteristics can be improved as compared with the printed circuit board of the related art shown in FIG. 3, as shown in FIG. 11.

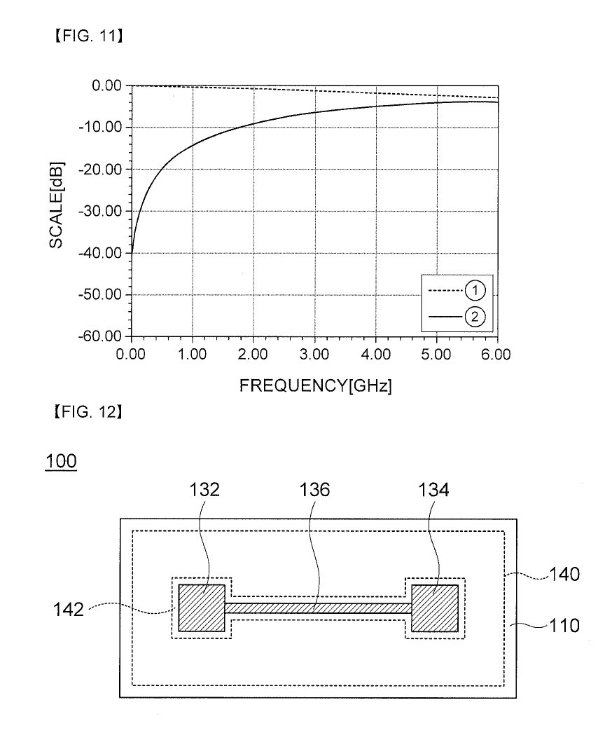

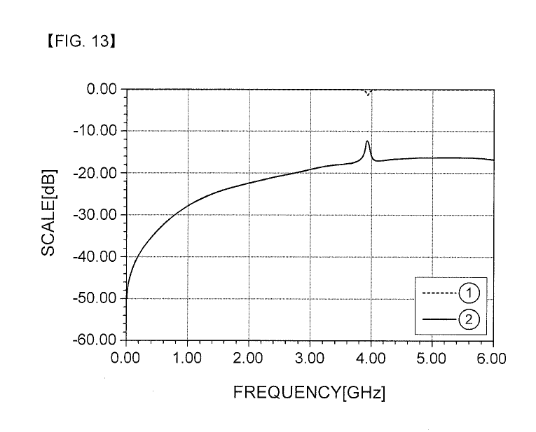

FIG. 12 is a plan view of the printed circuit board as shown in FIG. 10, of which a transmission line has a changed line width; and FIG. 13 is a graph showing signal transmitting characteristics of the printed circuit board shown in FIG. 12.

Referring to FIGS. 12 and 13, the transmission line 136 may have a wider line width than the transmission lines shown in FIGS. 5, 8, and 10. As such, it can be seen that, if the line width of the transmission line 136 is wide, the signal transmitting characteristics can be improved as compared with the printed circuit board of the related art as shown in FIG. 3, but when the line width of the transmission line 136 is too wide as compared with the transmission lines shown in FIGS. 5, 8, and 10, and thus, the signal transmitting characteristics cannot be significantly improved.

As set forth above, according to the printed circuit board of the present invention, the slots are formed at partial regions of the ground surface, facing the pads, and thus, the parasitic component generated at an impedance discontinuity point between the pads and the transmission line and the parasitic capacitance generated between the pads and the ground surface can be effectively removed, thereby improving signal transmitting characteristics.

Therefore, the printed circuit board capable of allowing high-density wiring and slim thickness can be achieved.

Furthermore, the performance of the entire system including the printed circuit board can be improved.

While the present invention has been shown and described in connection with the embodiments, it will be apparent to those skilled in the art that modifications and variations can be made without departing from the spirit and scope of the invention as defined by the appended claims .

What is claimed is:

1. A printed circuit board, comprising:
a dielectric substrate having a ground surface;
a plurality of pads formed on the dielectric substrate;
a transmission line transmitting a signal between the plurality of pads; and
slots formed in partial regions of the ground surface correspondingly to the pads.

2. The printed circuit board according to claim 1, wherein the slots are formed by partially removing the ground surface at positions facing the pads.

3. The printed circuit board according to claim 2, wherein the slots are formed by partially removing the ground surface at a position facing the transmission line.

4. The printed circuit board according to claim 1, wherein the dielectric substrate is made of a dielectric material.

5. The printed circuit board according to claim 1, wherein the number of slots is the same as the number of pads.

6. The printed circuit board according to claim 1, wherein the slot has a larger area than the pad.

7. The printed circuit board according to claim 1, wherein the ground surface is a conductive film coated on one surface of the dielectric substrate.

8. The printed circuit board according to claim 1, further comprising a core substrate having the dielectric substrate formed on one surface thereof.

9. The printed circuit board according to claim 8, wherein the dielectric substrate is constituted of first and second dielectric substrates formed on upper and lower surfaces of the core substrate.

10. The printed circuit board according to claim 9, wherein the first dielectric substrate has pads and a transmission line formed on an upper surface thereof and the second dielectric substrate has pads and a transmission line formed on a lower surface thereof.

11. The printed circuit board according to claim 9, wherein the first dielectric substrate has a ground surface formed on the lower surface thereof and the second dielectric substrate has a ground surface formed on the upper surface thereof.

12. The printed circuit board according to claim 8, wherein the dielectric substrate has a thickness of ⅕ times or less of that of the core substrate.

13. The printed circuit board according to claim 1, wherein the transmission line has a line width of ⅕ times or less of that of the pad.
